(19) United States
(12) Patent Application Publication
(10) Pub. No.: US 2019/0103349 A1
(43) Pub. Date: Apr. 4, 2019

(54) INTEGRATED EMBEDDED SUBSTRATE AND SOCKET

(71) Applicant: Intel Corporation, Santa Clara, CA (US)

(72) Inventors: Ram VISWANATH, Phoenix, AZ (US); Srikant NEKKANTY, Chandler, AZ (US)

(73) Assignee: Intel Corporation, Santa Clara, CA (US)

(21) Appl. No.: 15/721,844

(22) Filed: Sep. 30, 2017

(51) Int. Cl. H01L 23/50; H01L 23/34; H01R 13/24; H05K 3/30

(52) U.S. Cl. CPC H01L 23/50; H01L 23/34; H01R 13/2442; H01L 2924/15323; H01L 2924/14; H01L 2924/15788; H05K 3/305

(57) ABSTRACT

An apparatus is provided which comprises: a substrate material comprising one or more embedded copper planes, one or more plated through holes through the substrate material, one or more metal contacts, the metal contacts comprising a substantially straight section coupled with adhesive within the one or more plated through holes, and a cantilever spring section extending beyond a first surface of the substrate material, and one or more conductive contacts on a second surface of the substrate material, opposite the first surface, the conductive contacts coupled with the metal contacts. Other embodiments are also disclosed and claimed.

### BACKGROUND

As semiconductor devices get more advanced and further integrated, manufacturing sockets to interface with these devices is becoming increasingly complex. Some considerations include higher pin counts due to power and I/O demands, higher speed signals requiring improved signal quality, and larger package sizes.

Current land grid array (LGA) solutions are based on metal contacts inserted in plastic housing. Current solutions, however, have limited scalability to address high speed signaling such as co-ax signaling, impedance matching, etc.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-sectional view of an example integrated embedded substrate and socket, according to some embodiments,

FIGS. 2A-2H illustrate cross-sectional views of manufacturing steps of an integrated embedded substrate and socket, according to some embodiments,

FIG. 3 illustrates a cross-sectional view of an example system with an integrated embedded substrate and socket, according to some embodiments,

FIG. 4 illustrates a flowchart of a method of forming an integrated embedded substrate and socket, in accordance with some embodiments, and

FIG. 5 illustrates a smart device or a computer system or a SoC (System-on-Chip) which includes an integrated embedded substrate and socket, according to some embodiments.

### DETAILED DESCRIPTION

An integrated embedded substrate and socket is generally presented. In this regard, embodiments of the present disclosure enable printed circuit board based sockets. Multiple contact designs can be used and embedded in plated through holes (PTHs) or surface mounted on a substrate. Additionally, ground and power wells can be incorporated through the use of selective copper plating. One skilled in the art would appreciate that this approach may enable better ground connections and signal shielding among other benefits.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The terms “left,” “right,” “front,” “back,” “top,” “bottom,” “over,” “under,” and the like in the description and in the claims, if any, are used for descriptive purposes and not necessarily for describing permanent relative positions.

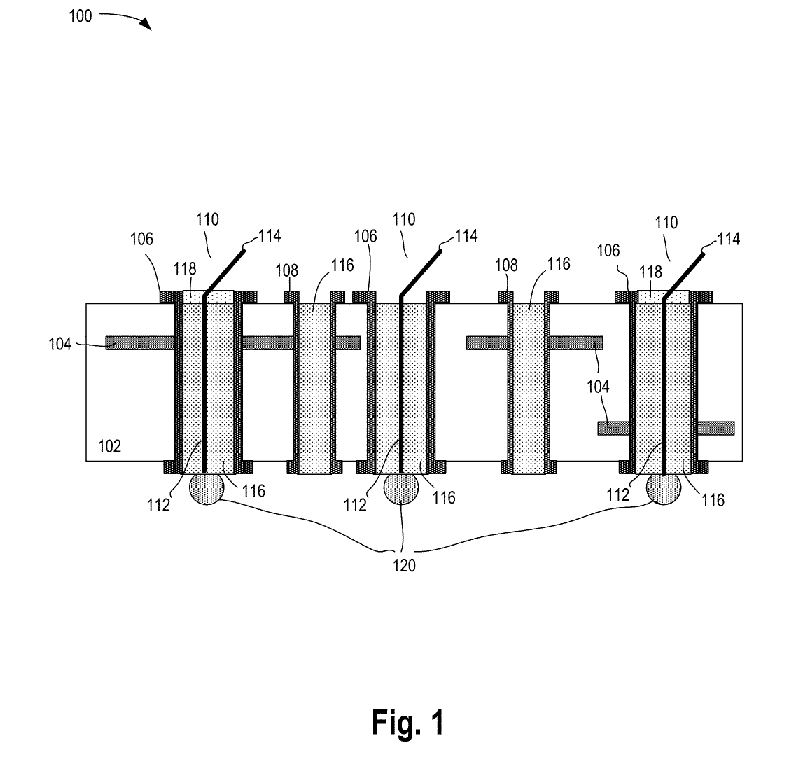

FIG. 1 illustrates a cross-sectional view of an example integrated embedded substrate and socket, according to some embodiments. As shown, socket 100 includes substrate 102, copper planes 104, large plated through holes 106, small plated through holes 108, metal contacts 110, buried contact section 112, cantilevered contact section 114, fill material 116, conductive material 118, and solder balls 120. In some embodiments, substrate 102 may be multi-layered laminated fiberglass, though socket 100 is not so limited and substrate 102 may include other materials such as cured epoxy, for example. Substrate 102 may include any number of copper planes 104, such as buried copper foil. In some embodiments, copper planes 104 may advantageously be coupled with power or ground or a system.

In some embodiments, socket 100 includes a combination of large plated through holes 106 and small plated through holes 108. In some embodiments, large plated through holes 106 include metal contacts 110, while small plated through holes 108 are conductively coupled with a grounded copper plane to improve the quality of signals to be transmitted through a nearby metal contact 110. Metal contacts 110 may have any design, composition, or orientation known in the art formed by manufacturing methods including, but not limited to, stamping, extrusion, etching, micro-forming, etc. In some embodiments, metal contacts 110 are land grid array (LGA) contacts. In some embodiments, metal contacts 110 include buried contact section 112 and cantilevered contact section 114, which may include a bend of at about 45 degrees (+/−15 degrees). While buried contact sections 112 are shown as being substantially straight (+/−10 degrees) and coaxial to the plated through holes, other shapes and orientations may be employed. In some embodiments, instead of being embedded in plated holes, metal contacts 110 may be mounted to a substrate surface, for example, metal contacts 110 may be soldered to a conductive surface contact.

Fill material 116 may fill the plated through holes and may embed metal contacts 110. In some embodiments, fill material is a polymer epoxy with insulative properties, which may provide co-axial shielding for metal contacts 110. Conductive material 118 may be included with some metal contacts 110 where it is desirable to couple the metal contact with the plated through hole and copper plane, for example in the case of a power or ground signal. Conductive material 118 may include solder or conductive paste or other conductive material. In some embodiments, conductive material 118 may be built into a metal contact design to create a conductive contact with the plated through hole. Solder balls 120 may allow socket 100 to couple with a system board for example. Other types of conductive contacts, such as lands, pins, bumps, etc. may be incorporated.

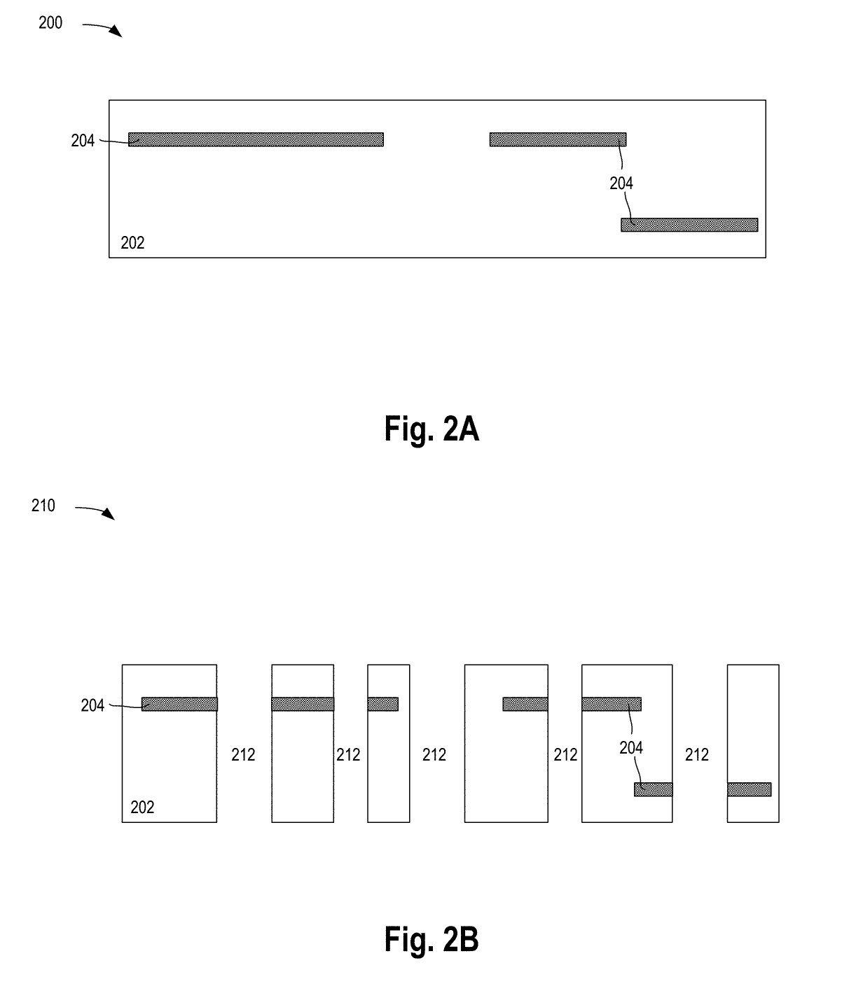

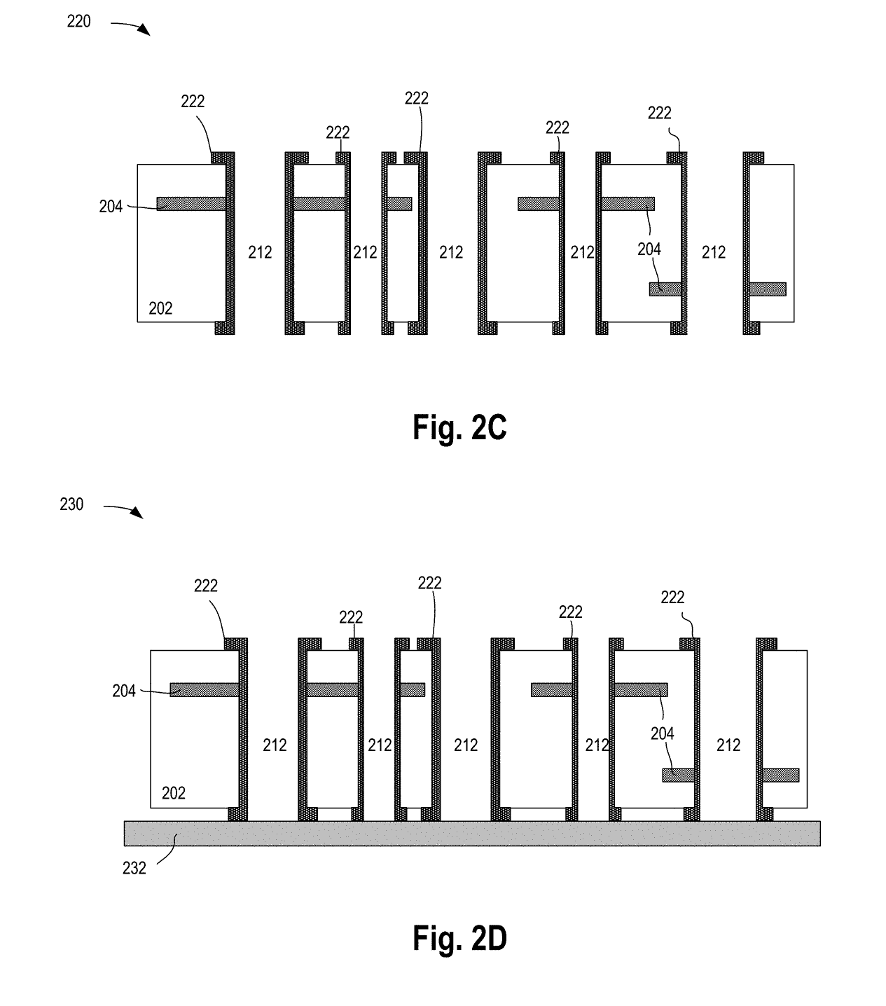

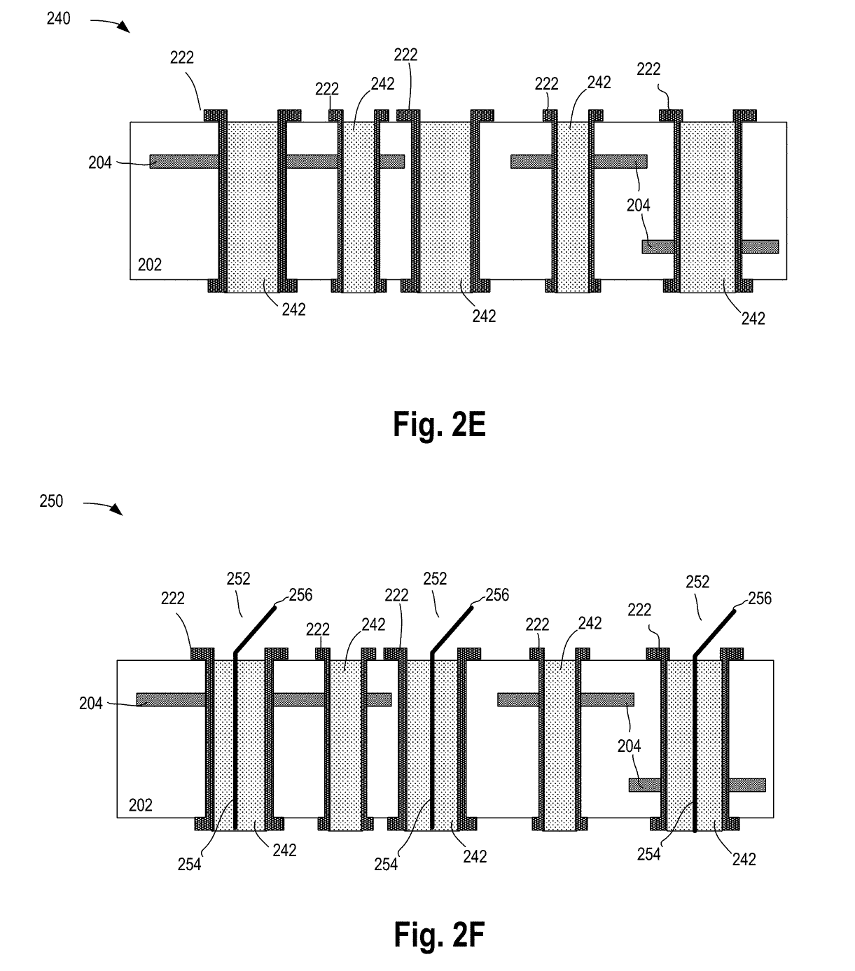

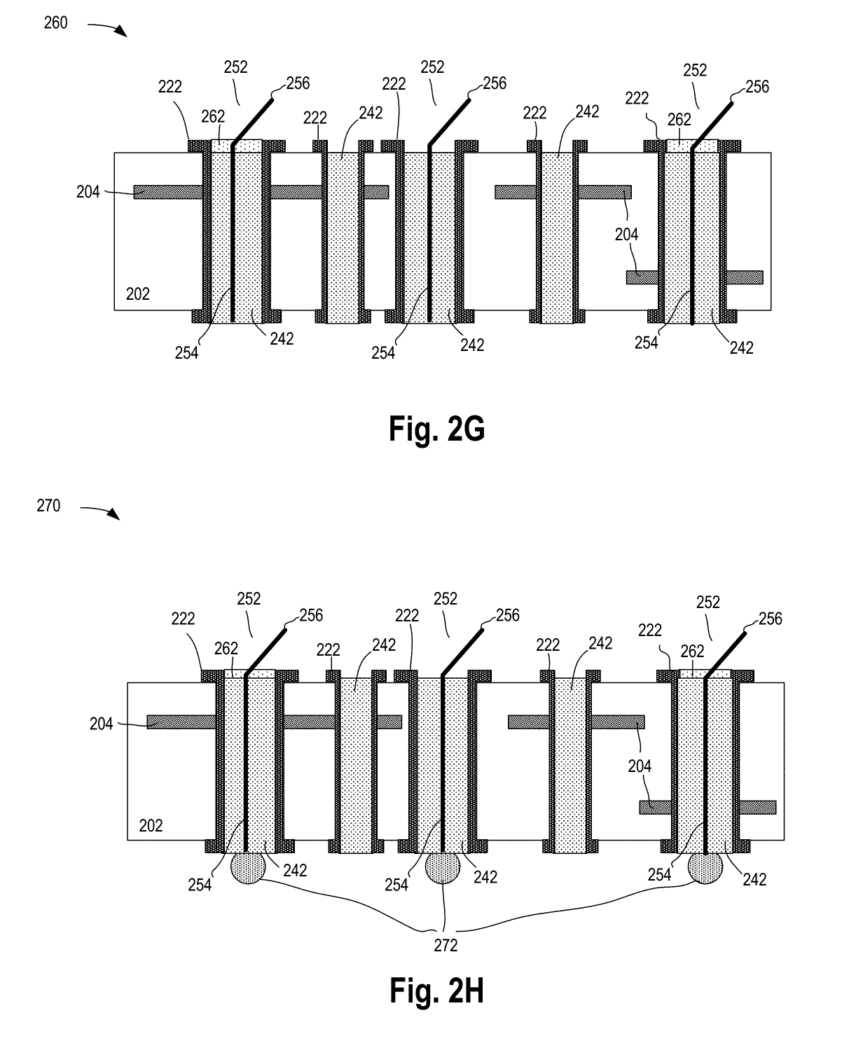

FIGS. 2A-2H illustrate cross-sectional views of manufacturing steps of an integrated embedded substrate and socket, according to some embodiments. As shown in FIG. 2A, assembly 200 includes substrate 202 and copper planes 204. In some embodiments, substrate 202 represents a laminated printed circuit board. Also, assembly 200 may include additional layers not shown.

FIG. 2B shows assembly 210, which may include holes 212 formed in and through substrate 202 and, in some cases, copper planes 204, as well. Conventional drilling or other known techniques may be employed to create holes 212.

As shown in FIG. 2C, assembly 220 may have had plating 222 deposited in holes 212. In some embodiments, plating 222 may involve electro or electroless copper plating. Where holed 212 were drilled through copper planes 204, plating 222 may couple with one or more copper planes 204.

Turning now to FIG. 2D, assembly 230 may include jig 232, which may close off one side of holes 212. In some embodiments, jig 232 may be a flat plate or may include protrusions to create voids in material about to be deposited.

FIG. 2E shows assembly 240, which may include fill material 242. In some embodiments, fill material 242 may be a curable epoxy, such as a polymer epoxy, that is flowed into holes 212 over jig 232.

As shown in FIG. 2F, for assembly 250 metal contacts 252 may be inserted into fill material 242. In some embodiments, if fill material is solid an additional drilling step may be necessary, however, in other embodiments, fill material 242 may not be cured and metal contacts 252 may be easily insertable. Metal contacts 252 may have any conceivable design and in some embodiments include a straight section 254 and a bent section 256. In some embodiments, straight section 254 is buried within fill material 242 while bent section 256 is cantilevered above a surface of substrate 202.

Turning now to FIG. 2G, assembly 260 may include conductive material 262 to couple select metal contacts 252 with the surrounding plated through hole 222. In some embodiments, conductive material 262 is a solder. In other embodiments, an alternative conductive fill material 242 may be used to fill those select plated through holes 222 which are to be coupled with metal contact 252.

FIG. 2H shows assembly 270, which may include solder balls 272, formed on a secondary side of substrate 202, opposite the side over which metal contacts 252 are protruding, coupled with metal contacts 252. In other embodiments, alternative conductive contacts may be used.

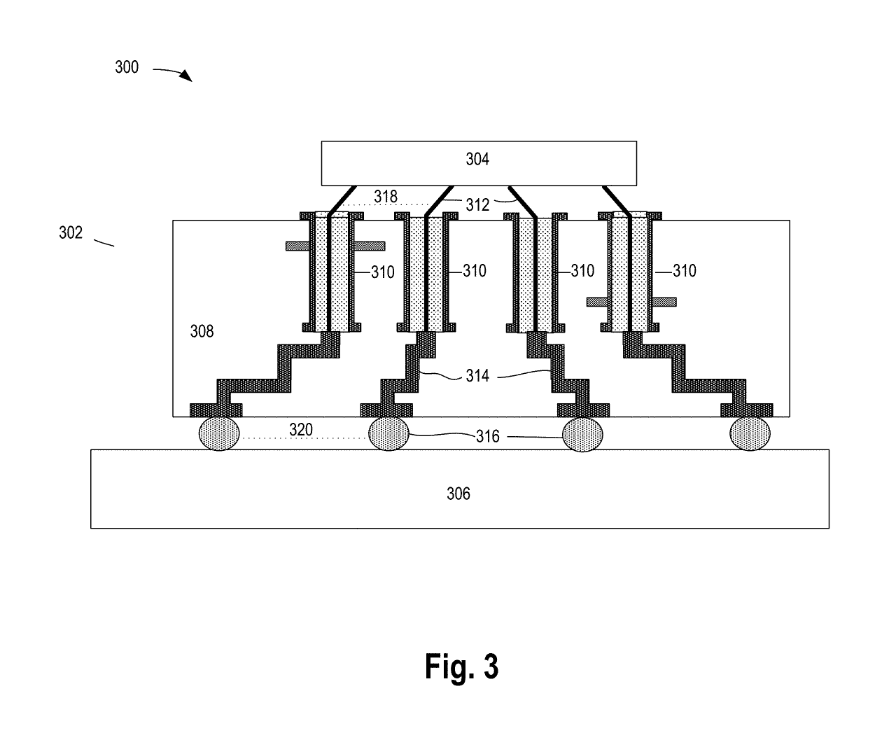

FIG. 3 illustrates a cross-sectional view of an example system with an integrated embedded substrate and socket, according to some embodiments. As shown, system 300 includes socket 302, integrated circuit device 304, system board 306, substrate 308, plated holes and/or vias 310, metal contacts 312, fanout routing 314, solder balls 316, metal contact pitch 318, and solder ball pitch 320. Integrated circuit device 304 may represent any type of device, including, but not limited to a processor, a controller, an SOC, or a transceiver. Integrated circuit device 304 may include lands (not shown) to contact with metal contacts 312. As shown, metal contacts 312 may include an opposing contact array with half the contacts oriented in an opposite direction from the other half, however, in other embodiments metal contacts 312 may be arranged in matching or non-matching arrays.

Fanout routing 314 may be build-up layers of metal and dielectric that couple metal contacts 312 at an end of plated holes and/or vias 310 to solder balls 316 and that translate metal contact pitch 318 to solder ball pitch 320. In some embodiments, solder ball pitch 320 is about one hundred percent coarser than metal contact pitch 318, while in other embodiments different pitch translations are possible. System board 306 may include other system components and may have solder pads (not shown) to couple with solder balls 316 of socket 302.

In some embodiments, one or more of plated holes and/or vias 310 may be conductively coupled with one or more solder balls 316, for example, via fanout routing 314. In this way, plated holes and/or vias 310 may act as a heatsink or heat spreader. One skilled in the art would appreciate that by spreading heat socket 302 may enable higher current transmissions.

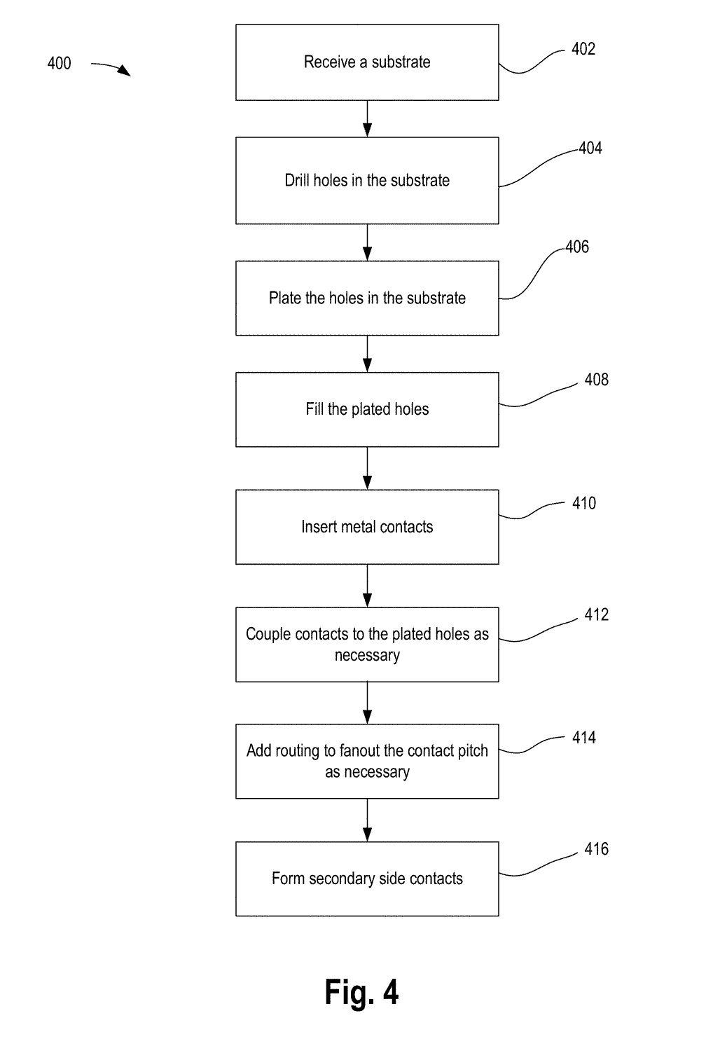

FIG. 4 illustrates a flowchart of a method of forming an integrated embedded substrate and socket, in accordance with some embodiments. Although the blocks in the flowchart with reference to FIG. 4 are shown in a particular order, the order of the actions can be modified. Thus, the illustrated embodiments can be performed in a different order, and some actions/blocks may be performed in parallel. Some of the blocks and/or operations listed in FIG. 4 are optional in accordance with certain embodiments. The numbering of the blocks presented is for the sake of clarity and is not intended to prescribe an order of operations in which the various blocks must occur. Additionally, operations from the various flows may be utilized in a variety of combinations.

Method 400 begins with receiving (402) a substrate. In some embodiments, a substrate, such as 202 may include buried copper layers, such as 204. Next, holes are drilled (404) in substrate. In some embodiments, holes may go through the substrate and the buried copper layers. In some embodiments, the holes may only partially go through a substrate and stop at a buried routing layer.

Then, the holes in the substrate may be plated (406). In some embodiments, copper plating covers the sides of the holes up to the substrate surface. Next, the plated holes may be filled (408) with fill material. In some embodiments, fill material 242 may be polymer epoxy or some other insulative material.

The method continues with inserting (410) metal contacts in the plated through holes. In some embodiments, the straight section of the metal contacts are embedded in the fill material while a bent section of the metal contacts is cantilevered above a substrate surface. Next, some of the metal contacts may be coupled (412) with the plated through holes. In some embodiments, metal contacts that are to transmit power or ground may advantageously be coupled with the surrounding plated through hole, perhaps by depositing solder.

In some embodiments, additional routing layers may be added (414) for example to fanout a contact pitch to a solder ball pitch. Finally, secondary side contacts may be formed (416), such as solder balls.

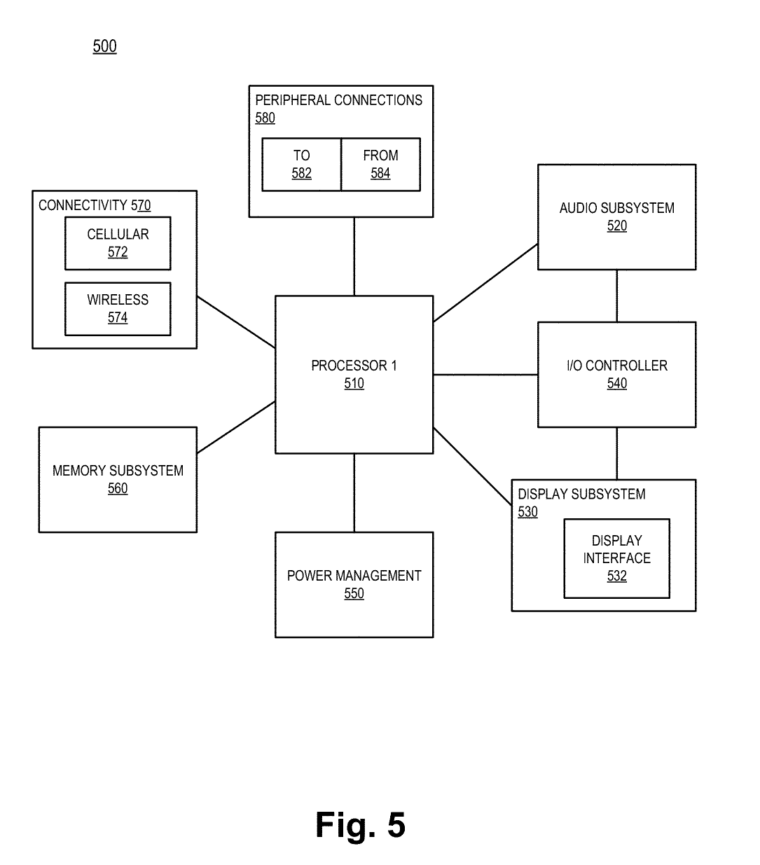

FIG. 5 illustrates a smart device or a computer system or a SoC (System-on-Chip) 500 which includes an integrated embedded substrate and socket, according to some embodiments. In some embodiments, computing device 500 represents a mobile computing device, such as a computing tablet, a mobile phone or smart-phone, a wireless-enabled e-reader, or other wireless mobile device. It will be understood that certain components are shown generally, and not all components of such a device are shown in computing device 500. In some embodiments, one or more components of computing device 500, for example processor 510 and/or memory subsystem 560, include an integrated embedded substrate and socket as described above.

For purposes of the embodiments, the transistors in various circuits and logic blocks described here are metal oxide semiconductor (MOS) transistors or their derivatives, where the MOS transistors include drain, source, gate, and bulk terminals. The transistors and/or the MOS transistor derivatives also include Tri-Gate and FinFET transistors, Tunneling FET (TFET), Square Wire, or Rectangular Ribbon Transistors, ferroelectric FET (FeFETs), or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, etc., may be used without departing from the scope of the disclosure.

In some embodiments, computing device 500 includes a first processor 510. The various embodiments of the present disclosure may also comprise a network interface within 570 such as a wireless interface so that a system embodiment may be incorporated into a wireless device, for example, cell phone or personal digital assistant.

In one embodiment, processor 510 can include one or more physical devices, such as microprocessors, application processors, microcontrollers, programmable logic devices, or other processing means. The processing operations performed by processor 510 include the execution of an operating platform or operating system on which applications and/or device functions are executed. The processing operations include operations related to I/O (input/output) with a human user or with other devices, operations related to power management, and/or operations related to connecting the computing device 500 to another device. The processing operations may also include operations related to audio I/O and/or display I/O.

In one embodiment, computing device 500 includes audio subsystem 520, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 500, or connected to the computing device 500. In one embodiment, a user interacts with the computing device 500 by providing audio commands that are received and processed by processor 510.

Display subsystem 530 represents hardware (e.g., display devices) and software (e.g., drivers) components that provide a visual and/or tactile display for a user to interact with the computing device 500. Display subsystem 530 includes display interface 532, which includes the particular screen or hardware device used to provide a display to a user. In one embodiment, display interface 532 includes logic separate from processor 510 to perform at least some processing related to the display. In one embodiment, display subsystem 530 includes a touch screen (or touch pad) device that provides both output and input to a user.

I/O controller 540 represents hardware devices and software components related to interaction with a user. I/O controller 540 is operable to manage hardware that is part of audio subsystem 520 and/or display subsystem 530. Additionally, I/O controller 540 illustrates a connection point for additional devices that connect to computing device 500 through which a user might interact with the system. For example, devices that can be attached to the computing device 500 might include microphone devices, speaker or stereo systems, video systems or other display devices, keyboard or keypad devices, or other I/O devices for use with specific applications such as card readers or other devices.

As mentioned above, I/O controller 540 can interact with audio subsystem 520 and/or display subsystem 530. For example, input through a microphone or other audio device can provide input or commands for one or more applications or functions of the computing device 500. Additionally, audio output can be provided instead of, or in addition to display output. In another example, if display subsystem 530 includes a touch screen, the display device also acts as an input device, which can be at least partially managed by I/O controller 540. There can also be additional buttons or switches on the computing device 500 to provide I/O functions managed by I/O controller 540.

In one embodiment, I/O controller 540 manages devices such as accelerometers, cameras, light sensors or other environmental sensors, or other hardware that can be included in the computing device 500. The input can be part of direct user interaction, as well as providing environmental input to the system to influence its operations (such as filtering for noise, adjusting displays for brightness detection, applying a flash for a camera, or other features).

In one embodiment, computing device 500 includes power management 550 that manages battery power usage, charging of the battery, and features related to power saving operation. Memory subsystem 560 includes memory devices for storing information in computing device 500. Memory can include nonvolatile (state does not change if power to the memory device is interrupted) and/or volatile (state is indeterminate if power to the memory device is interrupted) memory devices. Memory subsystem 560 can store application data, user data, music, photos, documents, or other data, as well as system data (whether long-term or temporary) related to the execution of the applications and functions of the computing device 500.

Elements of embodiments are also provided as a machine-readable medium (e.g., memory 560) for storing the computer-executable instructions. The machine-readable medium (e.g., memory 560) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 570 includes hardware devices (e.g., wireless and/or wired connectors and communication hardware) and software components (e.g., drivers, protocol stacks) to enable the computing device 500 to communicate with external devices. The computing device 500 could be separate devices, such as other computing devices, wireless access points or base stations, as well as peripherals such as headsets, printers, or other devices.

Connectivity 570 can include multiple different types of connectivity. To generalize, the computing device 500 is illustrated with cellular connectivity 572 and wireless connectivity 574. Cellular connectivity 572 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 574 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 580 include hardware interfaces and connectors, as well as software components (e.g., drivers, protocol stacks) to make peripheral connections. It will be understood that the computing device 500 could both be a peripheral device (“to” 582) to other computing devices, as well as have peripheral devices (“from” 584) connected to it. The computing device 500 commonly has a “docking” connector to connect to other computing devices for purposes such as managing (e.g., downloading and/or uploading, changing, synchronizing) content on computing device 500. Additionally, a docking connector can allow computing device 500 to connect to certain peripherals that allow the computing device 500 to control content output, for example, to audiovisual or other systems.

In addition to a proprietary docking connector or other proprietary connection hardware, the computing device 500 can make peripheral connections 580 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

In one example, an apparatus is provided comprising: a substrate material comprising one or more embedded copper planes; one or more plated through holes through the substrate material; one or more metal contacts, the metal contacts comprising a substantially straight section coupled with adhesive within the one or more plated through holes, and a cantilever spring section extending beyond a first surface of the substrate material; and one or more conductive contacts on a second surface of the substrate material, opposite the first surface, the conductive contacts coupled with the metal contacts.

Some embodiments also include separate power and ground planes embedded in the substrate material. In some embodiments, one or more plated through holes are coupled with a ground plane. In some embodiments, at least one of the one or more metal contacts is conductively coupled with a surrounding plated through hole. In some embodiments, the one or more conductive contacts comprise a pitch spacing coarser than a metal contact pitch spacing. In some embodiments, at least one of the one or more plated through holes is conductively coupled with at least one of the one or more conductive contacts at least in part to spread heat. In some embodiments, the substrate material comprises laminated fiberglass. In some embodiments, the adhesive comprises a polymer epoxy.

In another example, a system is provided comprising: an integrated circuit device package; and a socket coupled with the integrated circuit device package, wherein the socket comprises: a substrate material comprising one or more embedded copper planes; one or more plated through holes through the substrate material; one or more metal contacts, the metal contacts comprising a substantially straight section coupled with adhesive within the one or more plated through holes, and a cantilever spring section extending beyond a first surface of the substrate material; and one or more conductive contacts on a second surface of the substrate material, opposite the first surface, the conductive contacts coupled with the metal contacts.

Some embodiments also include separate power and ground planes embedded in the substrate material. In some embodiments, one or more plated through holes are coupled with a ground plane. In some embodiments, at least one of the one or more metal contacts is conductively coupled with a surrounding plated through hole. In some embodiments, the one or more conductive contacts comprise a pitch spacing coarser than a metal contact pitch spacing. In some embodiments, the cantilever spring sections comprise land grid array (LGA) contacts that interface with the integrated circuit device package. In some embodiments, the substrate material comprises laminated fiberglass. In some embodiments, the adhesive comprises a polymer epoxy.

In another example, a method is provided comprising: forming a substrate with one or more embedded copper planes; drilling one or more holes through the substrate; plating the one or more holes; inserting one or more metal contacts into the one or more plated holes, wherein the one or more metal contacts comprise a cantilever spring section extending beyond a first surface of the substrate; adhering the one or more metal contacts within the one or more plated holes; and forming one or more conductive contacts on a second surface of the substrate, opposite the first surface, the one or more conductive contacts coupled with the one or more metal contacts.

Some embodiments also include conductively coupling the one or more metal contacts with the one or more plated holes. In some embodiments, conductively coupling the one or more metal contacts with the one or more plated holes comprises depositing solder. In some embodiments, drilling one or more holes through the substrate comprises drilling a hole through the one or more embedded copper planes. In some embodiments, adhering the one or more metal contacts within the one or more plated holes comprises depositing a polymer epoxy. Some embodiments also include forming plated though holes coupled with an embedded ground plane. Some embodiments also include forming one or more routing layers coupled with the one or more metal contacts to translate a first pitch on the first surface to a second pitch on the second surface. In some embodiments, inserting one or more metal contacts into the one or more plated holes comprises inserting metal contacts in opposing orientations. In some embodiments, forming one or more conductive contacts on a second surface of the substrate comprises forming solder balls.

In another example, a system is provided comprising: a display subsystem; a wireless communication interface; and an integrated circuit device, the integrated circuit device coupled with a socket, the socket comprising: a substrate material comprising one or more embedded copper planes; one or more plated through holes through the substrate material; one or more metal contacts, the metal contacts comprising a substantially straight section coupled with adhesive within the one or more plated through holes, and a cantilever spring section extending beyond a first surface of the substrate material; and one or more conductive contacts on a second surface of the substrate material, opposite the first surface, the conductive contacts coupled with the metal contacts.

Some embodiments also include separate power and ground planes embedded in the substrate material. In some embodiments, one or more plated through holes are coupled with a ground plane. In some embodiments, at least one of the one or more metal contacts is conductively coupled with a surrounding plated through hole. In some embodiments, the one or more conductive contacts comprise a pitch spacing coarser than a metal contact pitch spacing. In some embodiments, the substrate material comprises laminated fiberglass.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1. An apparatus comprising:
a substrate material comprising one or more embedded copper planes;
one or more plated through holes through the substrate material;
one or more metal contacts, the metal contacts comprising a substantially straight section coupled with adhesive within the one or more plated through holes, and a cantilever spring section extending beyond a first surface of the substrate material; and
one or more conductive contacts on a second surface of the substrate material, opposite the first surface, the conductive contacts coupled with the metal contacts.

2. The apparatus of claim 1, further comprising separate power and ground planes embedded in the substrate material.

3. The apparatus of claim 2, wherein one or more plated through holes are coupled with a ground plane.

4. The apparatus of claim 3, wherein at least one of the one or more metal contacts is conductively coupled with a surrounding plated through hole.

5. The apparatus of claim 3, wherein the one or more conductive contacts comprise a pitch spacing coarser than a metal contact pitch spacing.

6. The apparatus of claim 3, wherein at least one of the one or more plated through holes is conductively coupled with at least one of the one or more conductive contacts at least in part to spread heat.

7. The apparatus of claim 3, wherein the substrate material comprises laminated fiberglass.

8. The apparatus of claim 3, wherein the adhesive comprises a polymer epoxy.

9. A system comprising:
an integrated circuit device package; and
a socket coupled with the integrated circuit device package, wherein the socket comprises:
a substrate material comprising one or more embedded copper planes;
one or more plated through holes through the substrate material;
one or more metal contacts, the metal contacts comprising a substantially straight section coupled with adhesive within the one or more plated through holes, and a cantilever spring section extending beyond a first surface of the substrate material; and
one or more conductive contacts on a second surface of the substrate material, opposite the first surface, the conductive contacts coupled with the metal contacts.

10. The system of claim 9, further comprising separate power and ground planes embedded in the substrate material.

11. The system of claim 10, wherein one or more plated through holes are coupled with a ground plane.

12. The system of claim 11, wherein at least one of the one or more metal contacts is conductively coupled with a surrounding plated through hole.

13. The system of claim 11, wherein the one or more conductive contacts comprise a pitch spacing coarser than a metal contact pitch spacing.

14. The system of claim 11, wherein the cantilever spring sections comprise land grid array (LGA) contacts that interface with the integrated circuit device package.

15. The system of claim 11, wherein the substrate material comprises laminated fiberglass.

16. The system of claim 11, wherein the adhesive comprises a polymer epoxy.

17. A method comprising:
forming a substrate with one or more embedded copper planes;
drilling one or more holes through the substrate;
plating the one or more holes;
inserting one or more metal contacts into the one or more plated holes, wherein the one or more metal contacts comprise a cantilever spring section extending beyond a first surface of the substrate;
adhering the one or more metal contacts within the one or more plated holes; and
forming one or more conductive contacts on a second surface of the substrate, opposite the first surface, the one or more conductive contacts coupled with the one or more metal contacts.

18. The method of claim 17, further comprising conductively coupling the one or more metal contacts with the one or more plated holes.

19. The method of claim 18, wherein conductively coupling the one or more metal contacts with the one or more plated holes comprises depositing solder.

20. The method of claim 18, wherein drilling one or more holes through the substrate comprises drilling a hole through the one or more embedded copper planes.

21. The method of claim 18, wherein adhering the one or more metal contacts within the one or more plated holes comprises depositing a polymer epoxy.

22. The method of claim 18, further comprising forming plated though holes coupled with an embedded ground plane.

23. The method of claim 18, further comprising forming one or more routing layers coupled with the one or more metal contacts to translate a first pitch on the first surface to a second pitch on the second surface.

24. The method of claim 18, wherein inserting one or more metal contacts into the one or more plated holes comprises inserting metal contacts in opposing orientations.

25. The method of claim 18, wherein forming one or more conductive contacts on a second surface of the substrate comprises forming solder balls.
